(19) United States
(12) Patent Application Publication
(10) Pub. No.: US 2025/0372402 A1
(43) Pub. Date: Dec. 4, 2025

(54) HERMETICALLY SEALED VIAS

(71) Applicant: SAMTEC, INC., New Albany, IN (US)

(72) Inventor: Mark Crain, New Albany, IN (US)

(21) Appl. No.: 19/220,830

(22) Filed: May 28, 2025

Related U.S. Application Data
(60) Provisional application No. 63/652,336, filed on May 28, 2024.

(51) Int. Cl. H01L 21/48; H01L 23/498

(52) U.S. Cl. CPC H01L 21/486; H01L 23/49827

(57) ABSTRACT

Electrical components, and associated methods for manufacturing, are described herein. In one aspect, an electrical component can include a substrate defining a first external surface and a second external surface opposite the first surface, and an internal surface that extends from the first external surface toward the second external surface; an electrically conductive layer that extends along the internal surface of the substrate between the first and second surfaces; and an electrically conductive end cap that is bonded to the electrically conductive layer and extends at least to the first surface.

### CROSS-REFERENCE TO RELATED APPLICATIONS

This application claims priority to U.S. Provisional Patent Application No. 63/652,336 (titled “Hermetically Sealed Vias”) filed May 28, 2024, the contents of which are hereby incorporated by reference in its entirety for any and all purposes.

### BACKGROUND

Thin glass or optically transparent dielectric substrates, such as fused silica/quartz, crystalline silicon, borosilicate, sapphire, or other dielectric substrates are created having a plurality of metallized vias that are metalized in such a manner as to create an electrical path. In the case of through vias, the electrical path extends from a first surface of the substrate to a second surface that can be opposite the first surface. The integrated circuit packaging industry refers to these substrates as interposers that can define electrical connections at opposed ends of the electrical vias. Vias fabricated into the interposer are typically very small, for example, from 5 μm to 100 μm in diameter and from 50 μm to 500 μm in depth from the first surface to the second surface. The number of vias per square centimeter may be in the hundreds or even thousands. Following the processing necessary to fabricate these vias the next step is to metalize the vias to provide for an electrically conductive pathway from one circuit plane or substrate to another.

Electrically conductive vias can be filled with copper (Cu) plating or electrically conductive pastes that contain Cu, glass frit, or both. Other approaches include introducing a molten metal into the substrate. However, the addition of fill can be costly, and the processes associated with filling the via can be both costly and time consuming.

What is needed are improved vias and associated methods for manufacturing.

### SUMMARY

Improved vias, and associated methods of manufacture, are described herein. In one aspect, an electrical component can include a substrate defining a first external surface and a second external surface opposite the first surface, and an internal surface that extends from the first external surface toward the second external surface; an electrically conductive layer that extends along the internal surface of the substrate between the first and second surfaces; and an electrically conductive end cap that is bonded to the electrically conductive layer and extends at least to the first surface.

The electrically conductive endcap, the internal surface, and the electrically conductive layer can define an electrically conductive via. The electrically conductive via can remain unfilled along the length of the via (e.g., between 10% and 98% of the length of the via), which can reduce the material and processing costs of manufacturing the via. For example, in lieu of an electrically conductive or nonconductive filler, the via can include a cavity along the length of the via. The cavity can be a gas, such as ambient air, or a vacuum. Alternatively, the electrically conductive via can be at least partially filed along the length of the via (such as between and including 10% and 98% of the length of the via) with a fill, such as at least one of an electrically conductive fill, an electrically non-conductive fill, both an electrically conductive fill and an electrically non-conductive fill, a combination of a fluid and a solid fill, a combination of a fluid and an electrically conductive fill, and a combination of a fluid and an electrically non-conductive fill.

An anti-wetting agent can facilitate the proper positioning and adhering of the end cap to the electrically conductive material. For example, the anti-wetting agent can be placed on a portion of the interior surface of the electrically conductive material. The anti-wetting agent can mitigate the end cap, such as when in liquid form, from bonding or adhering to the portions of the electrically conductive layer containing the anti-wetting agent. When dried or cured, a central region of the end cap can be unsupported from below, thereby forming the cavity in the via.

In another aspect, an electrical component can include a substrate defining a first external surface and a second external surface opposite the first external surface, and an internal surface that extends from the first external surface to the second external surface so as to define a hole; at least one electrically conductive layer that extends along the first surface and spans across the hole so as to define an end cap; and a fill disposed in the hole and surrounded by the internal surface, where the at least one electrically conductive layer, the fill, and the substrate define an electrically conductive via that extends from the first external surface to the second external surface.

In some cases, the fill can remain unbonded to the internal surfaces of the electrically conductive via. For example, the fill can be bonded to the endcap, or the fill can be free floating in the cavity. In some cases, the fill can be electrically conductive, such as a gold or gold alloy. During manufacture, a first electrically conductive layer can be adhered or bonded to an external surface of the substrate, or a second electrically conductive layer disposed atop the external surface. The first electrically conductive layer can span the opening of a via hole, thereby enclosing the hole when the first electrically conductive layer dries or cures. The internal surface of the substrate can be resistant to adhering or bonding to the first electrically conductive layer, such as by an anti-wetting agent having been applied to the internal surface, which can facilitate the first electrically conductive layer adhering or bonding to the external surface or the second electrically conductive layer. The substrate hole, being closed on one end by first electrically conductive layer, can then be filled with a filler, such as by electroplating gold or gold alloy. This via can provide for a via having highly efficient electric conductivity, while reducing the need for the filler to be bonded or adhered to the internal surface of the via.

### BRIEF DESCRIPTION OF THE DRAWINGS

FIG. 1 is a cross-sectional view of a substrate containing a via.

FIG. 2 is a cross-sectional view of a substrate containing layers for a via.

FIG. 3 is a cross-sectional view of a substrate containing a via.

FIG. 4 is a cross-sectional view of a substrate containing a via.

FIG. 5 a cross-sectional view of a substrate containing a via.

FIG. 6 a cross-sectional view of a substrate containing a via.

FIG. 7 a cross-sectional view of a substrate containing a via.

FIG. 8 a cross-sectional view of a substrate containing a via.

FIG. 9 is a cross-section view of a substrate containing a via placed in a bath.

FIG. 10 is a cross-sectional view of a substrate containing a via.

FIG. 11 is a cross-sectional view of a substrate containing a via.

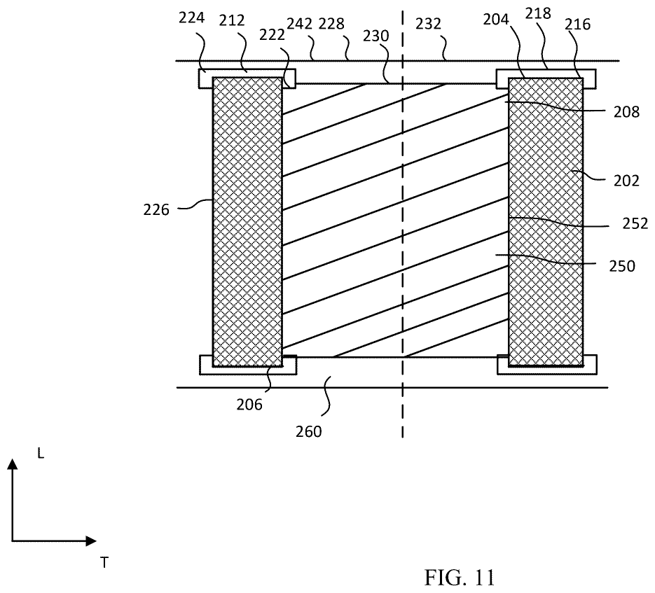

### DETAILED DESCRIPTION

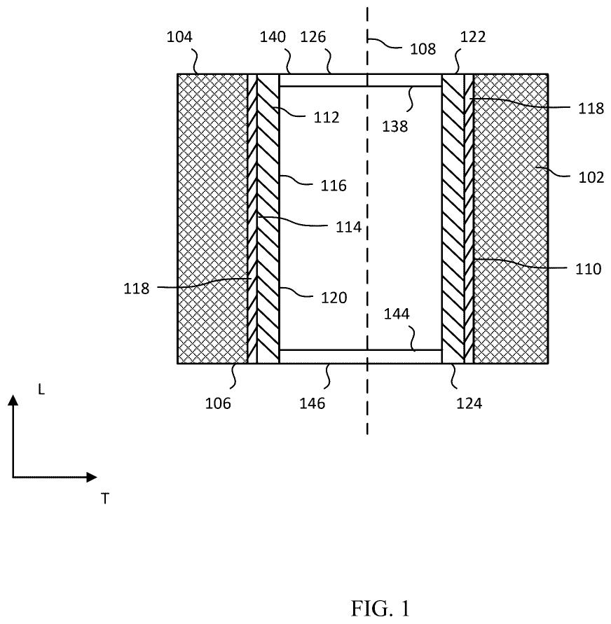

Turning to FIG. 1, an electrical component can include a substrate 102. The substrate 102 can be composed of glass, quartz, ceramic, sapphire, and the like. In some cases, the glass can be silica, such as soda-lime glass, lead silicate glass, borosilicate glass, aluminosilicate glass, fused silica glass, and the like. The substrate 102 can define a first external surface 104 and a second external surface 106 opposite the first external surface. The first external surface 104 and the second external surface 106 can be separated by a distance along a central axis 108. The central axis 108 can be in a direction that is orthogonal to a plane defined by the first external surface 104, a plane defined by the second external surface 106, or both. The central axis 108 can be in a direction parallel to a longitudinal direction (L) of the electrical component or substrate 102.

The substrate 102 can also define an internal surface 110. The internal surface 110 can extend from the first external surface 104 to the second external surface 106 along the direction of the central axis 108. The internal surface 110 can be continuous in a direction orthogonal to the central axis 108. For example, the internal surface 110 can circumferentially extend about the central axis 108 to form the shape of a pipe. However, other shapes about the central axis 108 can be formed as well, such as a box pipe, an hourglass (e.g., where the internal surface 110 tapers towards or away from the central axis 108), an “L” shape where a portion of the internal surface 110 extends in a traverse direction T orthogonal to the L direction, and the like. The internal surface 110 can be relatively uniform along the length of the substrate 102, where the length can be along the direction of the central axis 108. The internal surface 110 can be formed through various manufacturing processes in forming an electrically conductive via. For example, the internal surface 110 can be formed by mechanically drilling the substrate, lasing the substrate, etching the substrate, and the like. Thus, the internal surface 110 can define a hole, which can be formed by the drilling, etching, lasing, etc., process. The hole can include at least one opening, such as a first opening defined along the plane of the first external surface 104. In some cases, the hole can also define a second opening along the plane of the second external surface 106. In cases where the substrate 102 defines a hole having a single opening, the resulting via may be referred to as a blind via. In cases where the substrate 102 defines a hole having openings along both the first external surface 104 and the second external surface 106, the resulting via may be referred to as a through-hole via or a buried via.

The electrical component can also include an electrically conductive layer 112. The electrically conductive layer 112 can extend along the internal surface 110 of the substrate 102. For example, the electrically conductive layer 112 can extend along the direction of the central axis 108, such that the length of the electrically conductive layer 112 is along the central axis 108. The electrically conductive layer 112 can extend along the L direction of the substrate 102. A thickness of the electrically conductive layer 112 can be in the direction orthogonal to the central axis 108 or the L direction. The thickness of the electrically conductive layer 112 can be between 3 microns and 10 microns, 4 microns and 10 microns, 5 microns and 10 microns, 6 microns and 10 microns, 7 microns and 10 microns, 8 microns and 10 microns, 8 microns and 9 microns, and the like.

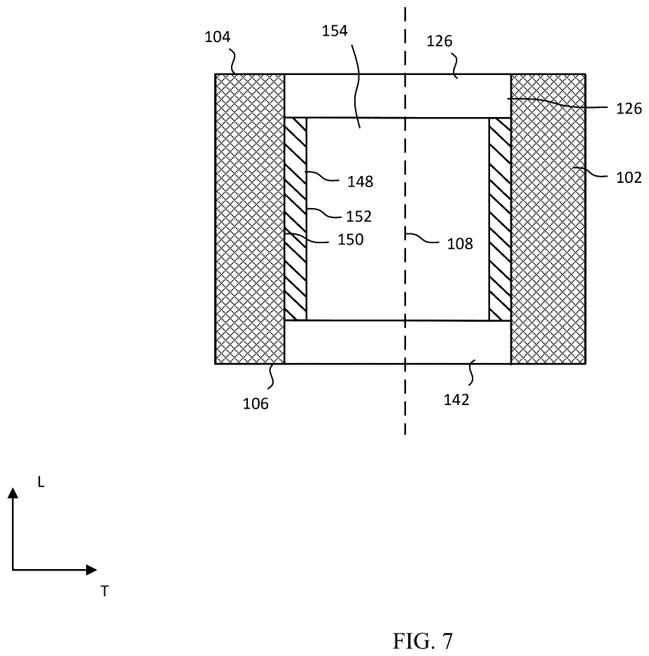

The electrically conductive layer 112 can further define a first surface 114 and a second surface 116. The first surface 114 can face the internal surface 110 of the substrate 102. In some cases, the first surface 114 can directly contact the internal surface 110, such as that shown in FIG. 7. In some cases, the first surface 114 can contact an adhesion layer disposed between the internal surface 110 and the first surface 114, such as that shown in FIG. 1. The first surface 114 can extend substantially from the first external surface 104 to the second external surface 106. In some cases, the first surface 114 can extend between the first external surface 104 and the second external surface 106.

The term “approximately,” “substantially,” and the like along with derivatives thereof are intended to mean considerable in extent or largely but not necessarily wholly (but can include wholly) that which is specified. As used herein, the term “substantially,” “approximately,” derivatives thereof, and words of similar import, when used to describe a size, shape, orientation, distance, spatial relationship, or other parameter includes the stated size, shape, orientation, distance, spatial relationship, or other parameter, and can also include a range up to 10% more and up to 10% less than the stated parameter, including 5% more and 5% less, including 3% more and 3% less, including 1% more and 1% less.

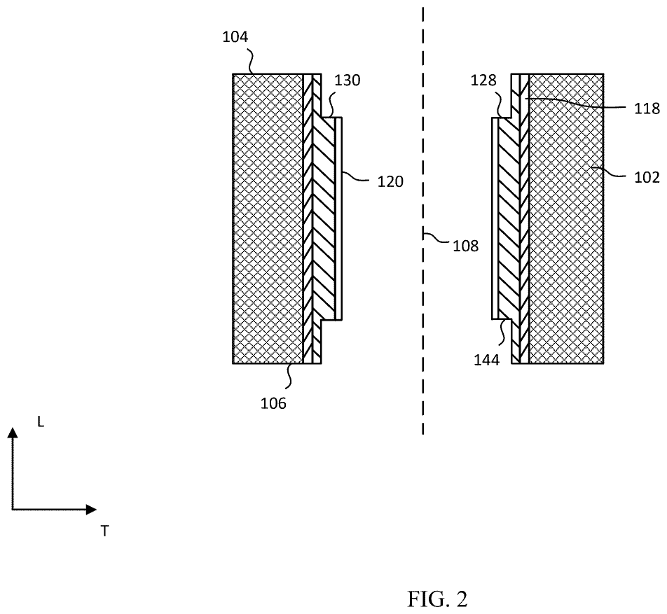

The second surface 116 can face the central axis 108. The second surface 116 can face the interior of the hole defined by the substrate 102. The second surface 116 can extend from between the first external surface 104 and the second external surface 106, as shown in FIG. 2. The second surface 116 can extend from the first external surface 104 to the second external surface 106, as shown in FIG. 1. Further, the electrically conductive layer 112 can define first and second terminal ends 122 and 124, respectively. The length of the electrically conductive layer 112 can terminate at the terminals ends 122 and 124. The first terminal end 122 can be disposed more proximate to the first external surface 104 compared to the second terminal end 124. Likewise, the second terminal end 124 can be disposed more proximate to the second external surface than the first terminal end 122.

In some cases, the first terminal end 122 can be coplanar with the first external surface 104, such that the first terminal end 122 is flush with the first external surface 104. In some cases, the first terminal end 122 can be recessed with respect to the first external surface 104, such that the first terminal end 122 is disposed within the hole formed by the internal surface 110. Thus, the first terminal end 122 can form a recess that spans from the second surface 116 to the adhesion layer 118, or the internal surface 110 along a direction orthogonal to the central axis 108.

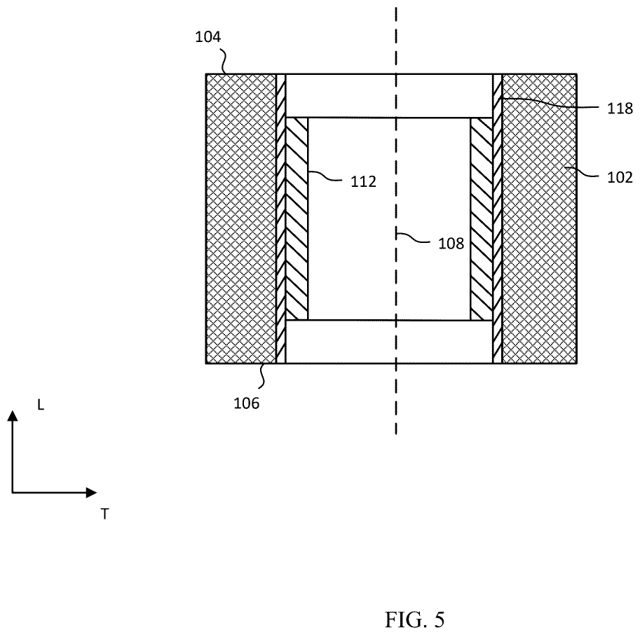

In some cases, the second terminal end 124 can be coplanar with the second external surface 106, such that the second terminal end 124 is flush with the second external surface 106. In some cases, the second terminal end 124 can be recessed with respect to the second external surface 106, such that the second terminal end 124 is disposed within the hole formed by the internal surface 110. Thus, the first terminal end 122 can form a recess that spans from the second surface 116 to the adhesion layer 118, or the internal surface 110 along a direction orthogonal to the central axis 108. Examples of these recessed terminal ends are shown in FIG. 5.

The electrically conductive layer 112 can be in substantially the same shape as the internal surface 110. For example, if the internal surface 110 forms a pipe as discussed above, the electrically conductive layer 112 can also take the shape of a pipe. If the internal surface 110 takes the shape of an hourglass or box pipe, the electrically conductive layer 112 can likewise take the shape of an hourglass or box pipe. The electrically conductive layer 112 can be disposed onto the internal surface 110, or alternatively onto an adhesion layer, through various manufacturing processes, such as electroplating, phase vapor deposition (PVD), atomic layer deposition (ALD), chemical vapor deposition (CVD), and the like. The electrically conductive layer 112 can be electrically conductive. For example, the electrically conductive layer 112 can be composed of any one of copper, silver, gold, platinum, aluminum, palladium. In some examples, the metal can be a pure metal, meaning that the metal is not alloyed with other metals. In other examples, the metal can be an alloy.

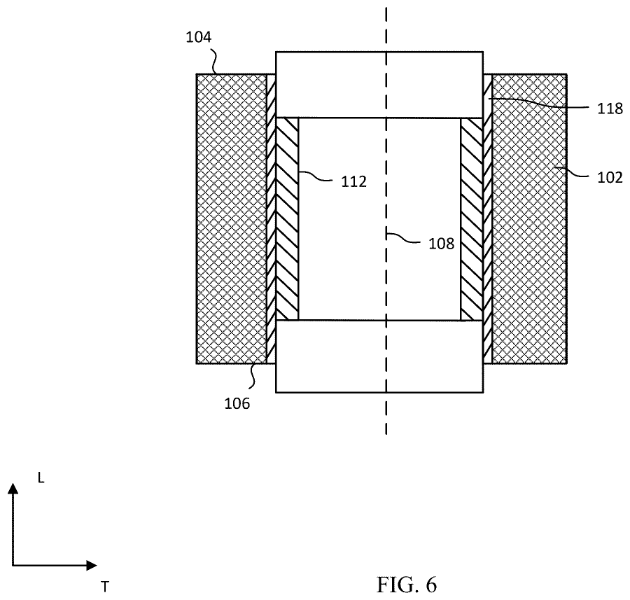

Turning to FIG. 2, the electrically conductive layer 112 can define a shoulder 128. The shoulder 128 can be a location where the electrically conductive layer transitions from having a first thickness, in a direction perpendicular to the central axis 108, to a second thickness. The first thickness can be greater than the second thickness. The portion of the electrically conductive layer 112 having the first thickness can terminate at the shoulder 128. The shoulder 128 can define a plane 130 that runs perpendicular to the direction of the central axis 108. The plane 130 can be recessed with respect to the plane defined by the first external surface 104. In some cases, such as shown in FIG. 2, a remaining portion of the electrically conductive layer 112 can continue extending along the direction of the central axis 108 and can terminate at the first external surface 104 (e.g., the end is flush with the first external surface 104). Alternatively, the remaining portion can terminate between the first external surface 104 and the plane 130, such that the remaining portion's terminal end is recessed with respect to the first external surface 104. Alternatively, the shoulder 128 can include no remaining portion, and thus the electrically conductive layer 112 can terminate at the shoulder 128 (e.g., as shown in FIGS. 6 and 7). The shoulder 128 can be formed by removing a portion of the electrically conductive layer 112 after disposal along the internal surface 110. For example, material from the electrically conductive layer 112 can be removed by etching, lasing, chemical-mechanical polishing (CMP), and the like.

The electrically conductive layer 112 can define a middle portion 132 and respective end portions 134 and 136. The middle portion 132 can extend along the central axis 108 and can terminate at the respective end portions 134 and 136. The respective end portions 134 and 136 can be defined by the change in thickness between the middle portion 132 and the respective end portions 134 and 136. The middle portion 132 can be more proximate to the second external surface 106 along the direction of the central axis 108 than the end portion 134. Likewise, the middle portion 132 can be more proximate to the first external surface 104 along the direction of the central axis 108 than the end portion 136. In some cases, the respective end portions 134 and 136 can be a shoulder, such as shoulder 128. In some cases, the respective end portions 134 and 136 can be a plane parallel to the plane defined by the first external surface 104, the plane defined by the second external surface 106, or both. The respective end portions 134 and 136 can be free of any wetting mitigation agent discussed in more detail below, whereas the middle portion 132 can include a wetting mitigation agent along the second surface 116.

In cases where the electrically conductive layer 112 includes a shoulder 128, the respective end portions 134 and 136 can be offset with respect to the middle portion 132 in an outward direction away from the central axis 108 of the electrically conductive via. The shoulder 128 can extend substantially along a direction perpendicular to the central axis 108.

The electrical component can also include an adhesion layer 118. The adhesion layer 118 can extend between the first external surface 104 and the second external surface 106. The adhesion layer 118 can extend from the first external surface 104 to the second external surface 106. The adhesion layer 118 can be electroplated, applied by ALD, CVD, PVD, and the like. The adhesion layer 118 can be electrically conductive. For instance, the adhesion layer 14 can be made of titanium, either as pure titanium or a titanium alloy. The titanium can be deposited to the inner surface 110 using physical vapor deposition. In other examples, the adhesion layer 118 can be made of tantalum, either as pure tantalum or a tantalum alloy such as tantalum nitride. The tantalum can be deposited to the inner surface 110 using atomic layer deposition. Similar to the electrically conductive layer, 112, portions of the adhesion layer 118 can be removed (e.g., along terminal ends), such as by wet etching, lasing, CMP, and the like.

The electrical component can include a wetting mitigation agent 120. The wetting mitigation agent 120 can mitigate material of an end cap from adhering or bonding to portions of the electrically conductive layer 112. For example, the wetting mitigation agent 120 can be disposed along surfaces of the electrically conductive layer 112 that are exposed from the inner surface 110 of the substrate 102. The wetting mitigation agent 120 can be disposed along at least a portion of the second surface 116 of the electrically conductive layer 112. The wetting mitigation agent 120 can be disposed along the first and second terminal ends 122 and 124. The wetting mitigation agent 120 can cover 10-98% of surfaces of the electrically conductive layer not adhered to the internal surface 110 of the substrate 102. The wetting mitigation agent 120 can cover 15-95% of surfaces of the electrically conductive layer not adhered to the internal surface 110 of the substrate 102. The wetting mitigation agent 120 can cover 20-90% of surfaces of the electrically conductive layer not adhered to the internal surface 110 of the substrate 102. The wetting mitigation agent 120 can cover 25-85% of surfaces of the electrically conductive layer not adhered to the internal surface 110 of the substrate 102. The wetting mitigation agent 120 can cover 30-80% of surfaces of the electrically conductive layer not adhered to the internal surface 110 of the substrate 102. The wetting mitigation agent 120 can cover 35-75% of surfaces of the electrically conductive layer not adhered to the internal surface 110 of the substrate 102. The wetting mitigation agent 120 can cover 35-70% of surfaces of the electrically conductive layer not adhered to the internal surface 110 of the substrate 102. The wetting mitigation agent 120 can cover 40-65% of surfaces of the electrically conductive layer not adhered to the internal surface 110 of the substrate 102. The wetting mitigation agent 120 can cover 45-60% of surfaces of the electrically conductive layer not adhered to the internal surface 110 of the substrate 102. The wetting mitigation agent 120 can cover 10-98% of the second surface 116 of the electrically conductive layer 112.

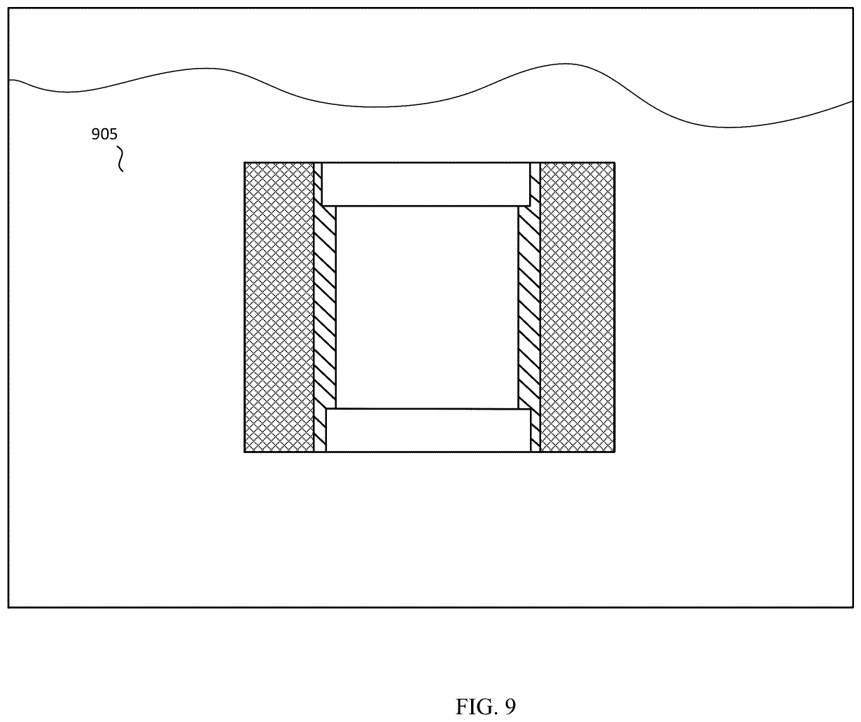

The wetting mitigation agent 120 can be a wetting mitigation coating. The coating can adhere or bond to the applied surfaces of the electrically conductive layer 112. The coating can be a liquid coating that can be cured through a curing or heating process. The coating can be applied to surfaces of the electrically conductive layer 112 through various manufacturing processes, such as placing the electrical component in a solution bath 905 (as shown in FIG. 9), solution spraying the electrical component In some cases, the coating can be a solid coating, such as a metal. The metal can be nickel. The coating can be applied through electroplated, applied by ALD, CVD, PVD, and the like. In one example, the wetting mitigation agent 120 can be applied by dipping the electrical connector, or the electrically conductive layer 112, into a 10% sulfuric acid bath (e.g., for 10 seconds). The electrical connector can then be rinsed and dried. The electrical connector 112 can then be dipped in a polysulfide solution, such as a 20:1 (DI:PS) solution (e.g., for 3-5 seconds), and then rinsed and dried. The respective faces of the electrical connector can be polished (e.g., with a 1 micron slurry), etched, and the like, rinsed, and dried, which may expose portions of the electrically conductive layer 112. The electrical connector can be dipped in a sulfuric acid solution (e.g., 10% sulfuric acid), rinsed, and dried. Solder can be disposed along the surfaces of the electrical connector, such as by solder ribbon melting of a solder dip, and then agitated, for forming an end cap.

As another example, the wetting mitigation agent 120 can be applied by dipping the electrically connector, or the electrically conductive layer 112, into a 10% sulfuric acid bath (e.g., for 10 seconds). The electrical connector can then be rinsed and dried. Electroless nickel can then be disposed along the surfaces of the electrical connector. The respective faces of the electrical connector can be polished (e.g., with a 1 micron slurry), etched, and the like, rinsed, and dried. The electrical connector can be dipped in a nitric acid solution (e.g., 10% nitric acid), rinsed, and dried. Solder can be disposed along the surfaces of the electrical connector, such as by solder ribbon melting of a solder dip, and then agitated, for forming an end cap.

As another example, the wetting mitigation agent 120 can be applied by dipping the electrically connector, or the electrically conductive layer 112, into a 10% sulfuric acid bath (e.g., for 10 seconds). The electrical connector can then be rinsed and dried. Electroless nickel phosphorus can then be disposed along the surfaces of the electrical connector. The respective faces of the electrical connector can be polished (e.g., with a 1 micron slurry), etched, and the like, rinsed, and dried. The electrical connector can be dipped in a hydrochloric acid solution (e.g., 10% HCl), rinsed, and dried. Solder can be disposed along the surfaces of the electrical connector, such as by solder ribbon melting of a solder dip, and then agitated, for forming an end cap.

As another example, the wetting mitigation agent 120 can be applied by dipping the electrically connector, or the electrically conductive layer 112, into a 10% sulfuric acid bath (e.g., for 10 seconds). The electrical connector can then be rinsed and dried. Electroplated iron or iron tungsten can then be disposed along the surfaces of the electrical connector. The respective faces of the electrical connector can be polished (e.g., with a 1 micron slurry), etched, and the like, rinsed, and dried. The electrical connector can be dipped in a hydrochloic acid solution (e.g., 10% HCl), rinsed, and dried. Solder can be disposed along the surfaces of the electrical connector, such as by solder ribbon melting of a solder dip, and then agitated, for forming an end cap.

As another example, the wetting mitigation agent 120 can be applied by dipping the electrically connector, or the electrically conductive layer 112, into a 10% sulfuric acid bath (e.g., for 10 seconds). The electrical connector can then be rinsed and dried. The electrical connector can then be base cleaned, such as with sodium hydroxide (NaOH), potassium hydroxide (KOH), and the like. Self assembled monolayer (SAM) deposition or an amine such as benzotriazole (BTA) can be deposited along the surfaces of the electrical connector. Plasma or wet polymerization can be performed on the SAM or amine deposition. The respective faces of the electrical connector can be polished (e.g., with a 1 micron slurry), etched, and the like, rinsed, and dried. The electrical connector can be dipped in a sulfuric acid solution (e.g., 10% sulfuric acid), rinsed, and dried. Solder can be disposed along the surfaces of the electrical connector, such as by solder ribbon melting of a solder dip, and then agitated, for forming an end cap.

The wetting mitigation agent 120 can modify the composition of the electrically conductive layer 112. For example, the surface to which the wetting mitigation agent 120 is applied to, such as the second surface 116, can have a different chemical composition than the rest of the electrically conductive layer 112, such as that of the first surface 114. In one example, the wetting mitigation agent 120 can be a polymer. In one example, the wetting mitigation agent 120 can be polysulfide. The wetting mitigation agent can chemically modify a surface of the electrically conductive layer.

The wetting mitigation agent 120 can mitigate or prevent an end cap from bonding or adhering to the surfaces of the electrically conductive layer 112 with the wetting mitigation agent 120. For example, a liquified material can be spread over an external surface of the substrate 102, or the substrate 102 can be placed in a bath of liquified material. The wetting mitigation agent 120 can mitigate or prevent the liquified material from bonding or adhering to the surfaces of the electrically conductive layer 112 having the wetting mitigation agent 120. For example, the liquified material can be positioned along surfaces of the electrically conductive material 112 that is free of the wetting mitigation agent 120. The liquified material can displace away from the surfaces having the wetting mitigation agent 120, and can instead position along the surfaces not having the wetting mitigation agent 120.

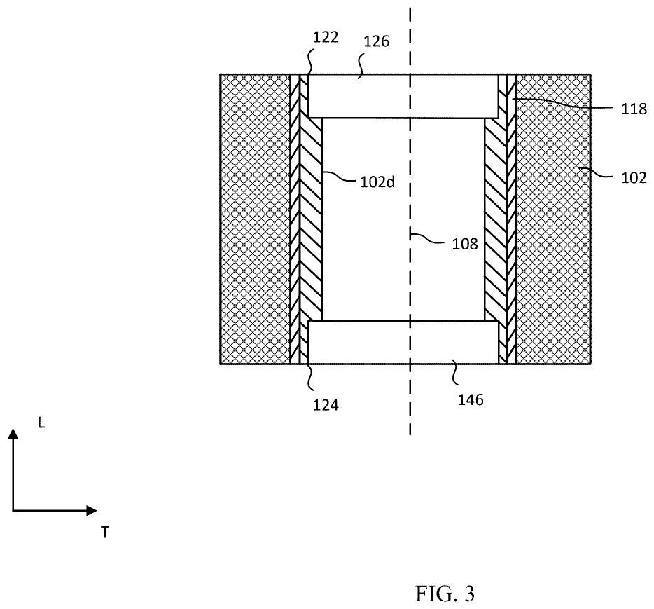

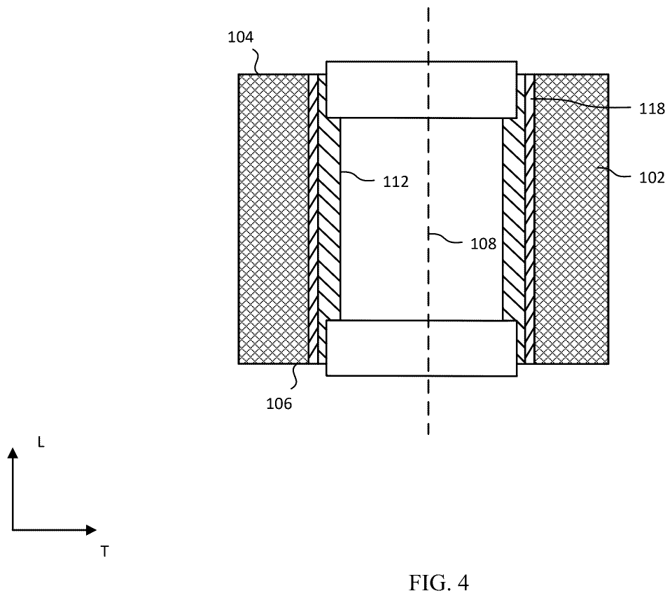

The electrical component can also have a first end cap 126. The first end cap 126 can be bonded to the electrically conductive layer 112. The first end cap 126 can be directly bonded to the electrically conductive layer 112. End regions of the first end cap 126 can be bonded or adhered to different points of the electrically conductive layer 112. In some cases, as shown in FIG. 1, end regions of the first end cap 126 can be a terminating end of the first end cap 126, where the terminating are the surfaces of the first end cap 126 that extend in the direction of the central axis 108, L direction, or length of the internal surface 110. In some cases, the end regions of the first end cap 126 can extend over a portion of the electrically conductive layer 112 in the direction of the central axis 108, L direction, or length of the internal surface 110. Thus, the end region of first end cap 126 can include the terminal end extending along the central axis 108, and a portion of the first end cap 126 that extends over the electrically conductive layer 112 in the direction of the central axis 108, such that the end cap extends over the electrically conductive layer so as to be aligned with the electrically conductive layer along a direction that defines the central axis. This can be seen in FIGS. 3-8. In cases where the electrically conductive layer 112 includes a shoulder 128, the first end cap 126 can be bonded to the shoulder 128.

The first end cap 126 can be bonded to a region of the electrically conductive layer 112 that is free of the wetting mitigation agent 120. Thus, the first end cap 126 can be bonded to the shoulder 128 of the electrically conductive layer 112 when the layer defines a shoulder. The first end cap 126 can be bonded to a terminal end 122 of the electrically conductive layer 112. The first end cap 126 can be bonded to an end region 134 of the electrically conductive layer 112. The first end cap 126 can be bonded to a recessed portion of the electrically conductive layer 112, and thus the first end cap 126 can be positioned at least partially in the recess. In some cases, the first end cap 126 can also abut the adhesion layer 118 along an outward direction away from the central axis 108, which is shown in FIG. 5. In some cases, the first end cap 126 can also abut the internal surface 110 along an outward direction away from the central axis 108, which is shown in FIG. 6.

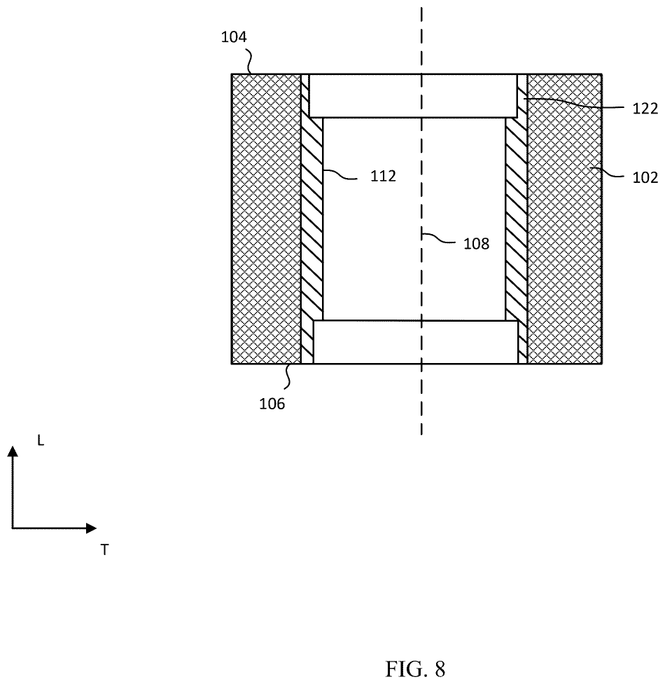

The first end cap 126 can extend from the electrically conductive layer 112 to at least the first external surface 102. The first end cap 126 can define a first surface 138 and a second surface 140. The first surface 138 can be more proximate to the second external surface 106 along the central axis 108 compared to the second surface 140. The first surface 138 can be separated from the second surface 140 along the central axis 108. At least a portion of the first surface 138 can be bonded to the electrically conductive layer 112. The second surface 140 can be the external surface of the first end cap 126. The second surface 140 can in some cases be flush with the first external surface 104, such that the second surface 140 is coplanar with the first external surface 104. Alternatively, the second surface 140 can extend away from the first external surface 104 along the direction of the central axis 108, such that the second surface 140 sits proud of the first external surface 104. In some cases, the second surface 140 can form a plane that is parallel to the plane of the first external surface 104, the second external surface 106, or both. Alternatively, the second surface 140 can depress or sag towards the second external surface 106, which may be due in part to the lack of physical support in a central region of the via when the first end cap 126 is applied to the substrate 102. Likewise, the first surface 138 can in some cases form a plane that is parallel to the plane of the first external surface 104, the second external surface 106, or both. Alternatively, the first surface 138 can depress or sag towards the second external surface 106, as shown in FIG. 8.

The first end cap 126 can be electrically conductive. The first end cap 126 can be composed of a metal. For example, the first end cap 126 can be composed of tin. However, the first end cap 126 can be composed of other metals, such as copper, gold, silver, platinum, titanium, aluminum, nickel, tungsten, molybdenum, zinc, barium, boron, and palladium. The metal can be heated to be liquified, and then applied to the first external surface 104, such that the liquified metal is spread across the opening of the first external surface 104. Alternatively, the substrate 102 can be placed in a bath of the liquified metal, and subsequently removed. The liquified metal can fail to adhere to the portions of the electrically conductive layer 112 having the wetting mitigation agent 120, and so the liquified metal may rest upon areas of the electrically conductive layer 112 without the wetting mitigation agent 120. When solidified, the liquified metal becomes the first end cap 126, which can then be processed in some cases to adjust the height of the first end cap 126 (e.g., by CMP etching, lasing, etc.). In some cases, the first end cap 126 can hermetically seal the electrically conductive via. The electrically conductive via can not be configured as a capacitor. The electrically conductive via can be substantially lead-free.

In some cases, the first end cap 126 can be composed of a metal alloy. For example, the first end cap 126 can be composed of gold tin, although other alloys of the metals described above can also be used. A first liquified metal can be placed along the first external surface 104 as discussed above. Then, a second liquified metal can be placed atop the first liquified metal. The two liquified metals may diffuse to form an alloy.

The first end cap 126 and the electrically conductive layer 112 can form an electrical pathway. The substrate 102, the electrically conductive layer 112, and the first end cap 126 can define an electrically conductive via that establishes an electrical path from the first external surface to the second external surface. The electrically conductive via can be elongate about the central axis 108, such that the second external surface 106 is opposite the first external surface 104 along the central axis 108.

The electrical component can also have a second end cap 142. The second end cap 142 can be bonded to the electrically conductive layer 112. The second end cap 142 can be directly bonded to the electrically conductive layer 112. End regions of the second end cap 142 can be bonded or adhered to different points of the electrically conductive layer 112. In some cases, as shown in FIG. 1, end regions of the second end cap 142 can be a terminating end of the second end cap 142, where the terminating ends are the surfaces of the second end cap 142 that extend in the direction of the central axis 108, L direction, or length of the internal surface 110. In some cases, the end regions of the second end cap 142 can extend over a portion of the electrically conductive layer 112 in the direction of the central axis 108, L direction, or length of the internal surface 110. Thus, the end region of second end cap 142 can include the terminal end extending along the central axis 108, and a portion of the second end cap 142 that extends over the electrically conductive layer 112 in the direction of the central axis 108. This can be seen in FIGS. 3-8. In cases where the electrically conductive layer 112 includes a shoulder 144, the second end cap 142 can be bonded to the shoulder 144.

The second end cap 142 can be bonded to a region of the electrically conductive layer 112 that is free of the wetting mitigation agent 120. Thus, the second end cap 142 can be bonded to the shoulder 144 of the electrically conductive layer 112 when the layer defines a shoulder. The second end cap 142 can be bonded to a terminal end 124 of the electrically conductive layer 112. The second end cap 142 can be bonded to an end region 136 of the electrically conductive layer 112. The second end cap 142 can be bonded to a recessed portion of the electrically conductive layer 112, and thus the second end cap 142 can be positioned at least partially in the recess. In some cases, the second end cap 142 can also abut the adhesion layer 118 along an outward direction away from the central axis 108, which is shown in FIG. 5. In some cases, the second end cap 142 can also abut the internal surface 110 along an outward direction away from the central axis 108, which is shown in FIG. 6.

The second end cap 142 can extend from the electrically conductive layer 112 to at least the second external surface 106. The second end cap 142 can define a first surface 144 and a second surface 146. The first surface 144 can be more proximate to the first external surface 104 along the central axis 108 compared to the second surface 146. The first surface 144 can be separated from the second surface 146 along the central axis 108. At least a portion of the first surface 144 can be bonded to the electrically conductive layer 112. The second surface 146 can be the external surface of the second end cap 142. The second surface 146 can in some cases be flush with the second external surface 106, such that the second surface 146 is coplanar with the second external surface 106. Alternatively, the second surface 146 can extend away from the second external surface 106 along the direction of the central axis 108, such that the second surface 146 sits proud of the second external surface 106. In some cases, the second surface 146 can form a plane that is parallel to the plane of the second external surface 106, the first external surface 104, or both. Alternatively, the second surface 146 can depress or sag towards the first external surface 104, which may be due in part to the lack of physical support in a central region of the via when the second end cap 142 is applied to the substrate 102. Likewise, the first surface 144 can in some cases form a plane that is parallel to the plane of the second external surface 106, the first external surface 104, or both. Alternatively, the first surface 144 can depress or sag towards the first external surface 104.

The second end cap 142 can be electrically conductive. The second end cap 142 can be composed of a metal. For example, the second end cap 142 can be composed of tin. However, the second end cap 142 can be composed of other metals, such as copper, gold, silver, platinum, titanium, aluminum, nickel, tungsten, molybdenum, zinc, barium, boron, and palladium. The metal can be heated to be liquified, and then applied to the second external surface 106, such that the liquified metal is spread across the opening of the second external surface 106. Alternatively, the substrate 102 can be placed in a bath of the liquified metal, and subsequently removed. The liquified metal can fail to adhere to the portions of the electrically conductive layer 112 having the wetting mitigation agent 120, and so the liquified metal may rest upon areas of the electrically conductive layer 112 without the wetting mitigation agent 120. When solidified, the liquified metal becomes the second end cap 142, which can then be processed in some cases to adjust the height of the second end cap 142 (e.g., by CMP etching, lasing, etc.). In some cases, the second end cap 142 can hermetically seal the electrically conductive via.

In some cases, the second end cap 142 can be composed of a metal alloy. For example, the second end cap 142 can be composed of gold tin, although other alloys of the metals described above can also be used. A first liquified metal can be placed along the second external surface 106 as discussed above. Then, a second liquified metal can be placed atop the first liquified metal. The two liquified metals may diffuse to form an alloy.

The second end cap 142 and the electrically conductive layer 112 can form an electrical pathway. The substrate 102, the electrically conductive layer 112, the first end cap 126, and the second end cap 412 can define an electrically conductive via that establishes an electrical path from the first external surface to the second external surface. The electrically conductive via can be elongate about the central axis 108, such that the second external surface 106 is opposite the first external surface 104 along the central axis 108.

The internal surfaces of the electrically conductive via can form a cavity which does not contain solids or liquids. For example, in some cases a combination of the electrically conductive layer 112, the internal surface 110, the wetting mitigation agent 120, and the adhesion layer 118 can define a sidewall 148 of the electrically conductive via. The sidewall 148 can define the innermost elongate surface or surfaces of the electrically conductive via that define the cavity of the via. The sidewall 148 can extend from the first external surface 104 to the second external surface 106 along the direction of the central axis 108. The sidewall 148 can extend from the first surface of the first end cap to the first surface of the second end cap. The sidewall 148 can extend from the first surface of the first or second end cap to a top or bottom surface of the substrate 102 (for example, in a blind via). For example, in FIG. 1, the sidewall 148 may be the electrically conductive layer 112. In FIG. 2, the sidewall 148 may be the wetting mitigation agent 120 and the electrically conductive layer 112. In FIG. 5, the sidewall 148 may be the electrically conductive layer 112 and the adhesion layer 118. In FIG. 7, the sidewall 148 may be the electrically conductive layer 112 and the internal surface 110 of the substrate 102.

Turning to FIG. 7, the sidewall 148 can include a first surface 150 and a second surface 152. The first surface 150 can extend along the internal surface 110 of the substrate 102. The first surface 150 can extend along the direction of the central axis 108. The first surface 150 can extend along the L direction. The first surface 150 can face the internal surface 110 of the substrate 102. The first surface 150 can adhere or bond to the internal surface 110 of the substrate 102. The second surface 152 can extend along the direction of the central axis 108. The second surface 152 can extend along the L direction. The second surface 152 can face opposite of the first surface 150. The second surface 152 can face the central axis 108. The second surface 152 can face the defined cavity. The second surface 152 can be defined in part by the wetting mitigation agent 120. The second surface 152 can be defined in part by the second surface 116 of the electrically conductive layer 112. The second surface 152 can be defined in part by the adhesion layer 118. The second surface 152 can be defined in part by the internal surface 110 of the substrate. The first surface 150 of the sidewall 148 can be defined in part by the first surface 114 of the electrically conductive layer 112. The first surface 150 can be defined in part by the adhesion layer 118. The first surface 150 can be defined in part by the internal surface 110 of the substrate 102.

The sidewall 148, the first end cap 126, and the second end cap 142 can define a cavity 154. The cavity 154 can remain unfilled of any solid materials. The cavity 154 can be a vacuum. The cavity 154 can be filled with a gas. The gas can be ambient air. The gas can be an inert gas. During manufacture, the electrical component can be placed in vacuum prior, during, or both, to disposing the liquified metal for the end caps, as discussed above. the electrical component can be placed in an inert gas prior, during, or both, to disposing the liquified metal for the end caps. When the liquified metal solidifies, the cavity 154 is formed, and can be filled with the ambient gas surrounding the electrical component at the time of disposing the liquified metal on the substrate 102. The electrically conductive via can be unfilled between 10-98% of a length of the electrically conductive via, with the length of the via running along the direction of the central axis 108. The electrically conductive via can be unfilled between 15-95% of a length of the electrically conductive via. The electrically conductive via can be unfilled between 20-90% of a length of the electrically conductive via. The electrically conductive via can be unfilled between 20-85% of a length of the electrically conductive via. The electrically conductive via can be unfilled between 25-80% of a length of the electrically conductive via. The electrically conductive via can be unfilled between 30-75% of a length of the electrically conductive via. The electrically conductive via can be unfilled between 35-70% of a length of the electrically conductive via. The electrically conductive via can be unfilled between 40-65% of a length of the electrically conductive via. The electrically conductive via can be unfilled between 45-60% of a length of the electrically conductive via.

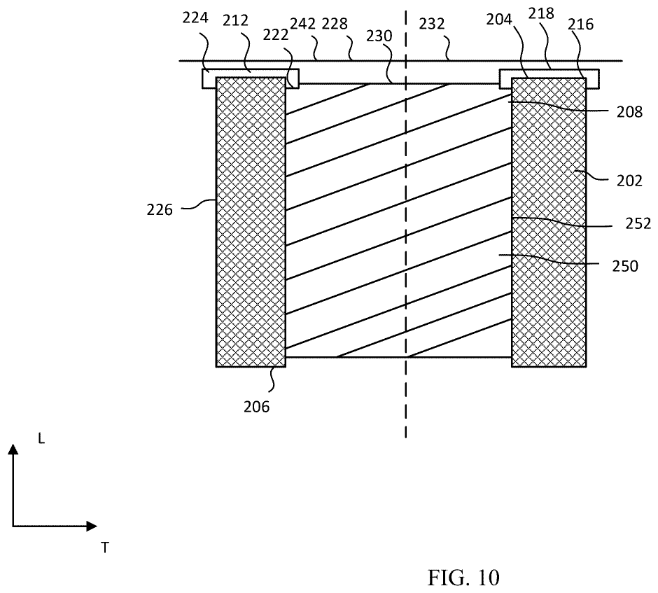

Turning to FIG. 10, an electrical component can include a substrate 202. The substrate 202 can be composed of glass, quartz, ceramic, sapphire, and the like. In some cases, the glass can be silica, such as soda-lime glass, lead silicate glass, borosilicate glass, aluminosilicate glass, fused silica glass, and the like. The substrate 202 can define a first external surface 204 and a second external surface 206 opposite the first external surface. The first external surface 204 and the second external surface 206 can be separated by a distance along a central axis 208. The central axis 208 can be in a direction that is orthogonal to a plane defined by the first external surface 204, a plane defined by the second external surface 206, or both. The central axis 208 can be in a direction parallel to the L direction of the electrical component or substrate 202.

The substrate 202 can also define an internal surface 210. The internal surface 210 can extend from the first external surface 204 to the second external surface 206 along the direction of the central axis 208. The internal surface 210 can be continuous in a direction orthogonal to the central axis 208. For example, the internal surface 210 can circumferentially extend about the central axis 208 to form the shape of a pipe. However, other shapes about the central axis 208 can be formed as well, such as a box pipe, an hourglass (e.g., where the internal surface 210 tapers towards or away from the central axis 208), an “L” shape where a portion of the internal surface 210 extends in the T direction T orthogonal to the L direction, and the like. The internal surface 210 can be relatively uniform along the length of the substrate 202, where the length can be along the direction of the central axis 208. The internal surface 210 can be formed through various manufacturing processes in forming an electrically conductive via. For example, the internal surface 210 can be formed by mechanically drilling the substrate, lasing the substrate, etching the substrate, and the like. Thus, the internal surface 210 can define a hole, which can be formed by the drilling, etching, lasing, etc., process. The hole can include at least one opening, such as a first opening defined along the plane of the first external surface 204. The hole can also define a second opening along the plane of the second external surface 206.

The electrical component can also include a first electrically conductive layer 212. The first electrically conductive layer 212 can extend along the first external surface 204 of the substrate 202. For example, the first electrically conductive layer 212 can extend along a direction perpendicular to the central axis 208. The first electrically conductive layer 212 can extend along the T direction of the substrate 202. The first electrically conductive layer 212 can further define a first surface 216 and a second surface 218. The first surface 216 can face the first external surface 210 of the substrate 202. In some cases, the first surface 216 can directly contact the first external surface 204. In some cases, the first surface 216 can contact an adhesion layer disposed between the first external surface 204 and the first surface 216. The first surface 216 can extend over the first external surface 204. The second surface 218 can face opposite the first surface 216. The second surface 116 can face the interior of the hole defined by the substrate 102. The second surface 218 can extend over the first external surface 204.

Further, the first electrically conductive layer 212 can define first and second terminal ends 222 and 224, respectively. The length of the first electrically conductive layer 212 can terminate at the terminals ends 222 and 224. The first terminal end 222 can be disposed more proximate to the internal surface 210 compared to the second terminal end 224. In some cases, the first terminal end 222 can be coplanar with the first external surface 204, such that the first terminal end 222 extends in the direction of the central axis 208 along the internal surface 210. In some cases the first terminal end 222 can terminate along the first external surface 204, such that the terminal end 222 fails to enter any gap defined by the internal surface 210. Likewise, the second terminal end 224 can be coplanar with the first external surface 206, such that the second terminal end 224 extends along the direction of the central axis 108 and along an external surface 226 of the substrate 202. In some cases the second terminal end 224 can terminate along the first external surface 204, such that the second terminal end 224 fails to extend along the direction of the central axis 208.

The first electrically conductive layer 212 can be disposed onto the first external surface 204, or alternatively onto an adhesion layer, through various manufacturing processes, such as electroplating, PVD, ALD, CVD, and the like. The first electrically conductive layer 212 can be electrically conductive. For example, the first electrically conductive layer 212 can be composed of any one of copper, silver, gold, platinum, aluminum, palladium. In some examples, the metal can be a pure metal, meaning that the metal is not alloyed with other metals. In other examples, the metal can be an alloy.

The electrical component can also have a second electrically conductive layer 228. The second electrically conductive layer 228 can be bonded to the first electrically conductive layer 212. The second electrically conductive layer 228 can be directly bonded to the first electrically conductive layer 212. Further, the second electrically conductive layer 228 may span an opening defined by the internal surface 210 of the 202. For example, the second electrically conductive layer 228 can define a plane that is parallel to a plane defined by the length of the first electrically conductive layer 212. The second electrically conductive layer 212 can define a first surface 230 and a second surface 232. The first surface 230 can extend perpendicular over the first external surface 204 and can span the opening defined by the internal surface 210 of the substrate 202. The first surface 230 can bond or adhere to the second surface 218 of the first electrically conductive layer 212. The first surface 230 can bond or adhere to the first terminal end 222 of the first electrically conductive layer 212. The second surface 232 can face opposite the first surface 230. The second electrically conductive layer 228 can be disposed atop the first electrically conductive layer 212. During manufacturing, the second electrically conductive layer 228 can be liquified and disposed atop the first electrically conductive layer 212. Alternatively, the substrate 202 can be placed in a bath of the liquified metal for the second electrically conductive layer 228. The material of the second electrically conductive layer 228 may fail to adhere or bond to the other surfaces of the substrate 202, such as the internal surface 210 and the external surface 206 (e.g., due to the composition of the substrate 202 or a wetting mitigation agent 240). The liquified metal can cool and solidify thereby forming a first end cap 242. The first end cap 242 can include the second electrically conductive layer 228, the first electrically conductive layer 212, or both.

The second surface 232 can in some cases be flush with the first external surface 204, such that the second surface 232 is coplanar with the first external surface 204. Alternatively, the second surface 232 can extend away from the first external surface 204 along the direction of the central axis 208, such that the second surface 232 sits proud of the first external surface 204. In some cases, the second surface 232 can form a plane that is parallel to the plane of the first external surface 204, the second external surface 206, or both. Alternatively, the second surface 232 can depress or sag towards the second external surface 206, which may be due in part to the lack of physical support in a central region of the via when the first end cap 242 is applied to the substrate 202. Likewise, the first surface 230 of the second electrically conductive layer 228 can in some cases form a plane that is parallel to the plane of the first external surface 204, the second external surface 206, or both. In some cases, the first surface 230 can depress or sag towards the second external surface 206.

The second electrically conductive layer 228 can be electrically conductive. The second electrically conductive layer 228 can be composed of a metal. For example, the second electrically conductive layer 228 can be composed of tin. However, the second electrically conductive layer 228 can be composed of other metals, such as copper, gold, silver, platinum, titanium, aluminum, nickel, tungsten, molybdenum, zinc, barium, boron, and palladium. When solidified, the first end cap can be processed in some cases to adjust the height of the first end cap 242 (e.g., by CMP etching, lasing, etc.). In some cases, the first end cap 242 can hermetically seal an electrically conductive via formed along the substrate 202. The electrically conductive via can not be configured as a capacitor. The electrically conductive via can be substantially lead-free.

In some cases, the second electrically conductive layer 228 can be composed of a metal alloy. For example, the second electrically conductive layer 228 can be composed of gold tin, although other alloys of the metals described above can also be used. A first liquified metal can be placed along the first external surface 204 as discussed above. Then, a second liquified metal can be placed atop the first liquified metal. The two liquified metals may diffuse to form an alloy.

The internal surface 110 can also define a hole 250. The hole 250 can extend from the first external surface 204 and the second external surface 206. The hole 250 can be partially filled with a fill 252. The fill 252 can be bonded or adhered to the first electrically conductive layer 212, the second electrically conductive layer 228, or both. The fill 252 can be uncoupled to the internal surface 210. In some cases, the fill 252 can be free floating in the hole 250, and can remain free of bonding or adhering to the internal surface 210, the first electrically conductive layer 212, and the second electrically conductive layer 228. The fill 252 can extend from the first electrically conductive layer 212 towards the second external surface 206 along the direction of the central axis 208. The fill can 252 extend from the first external surface 204 towards the second external surface 206. In some cases, the fill 252 can extend from the first external surface 204 to the second external surface 206. The fill 252 can be comprised of gold. However, the fill 252 can be composed of other metals, such as copper, silver, platinum, titanium, aluminum, nickel, tungsten, molybdenum, zinc, barium, boron, and palladium. The fill 252 can be disposed into the hole 250, such as by electroplating, PVD, ALD, CVD, and the like. In some cases, the first end cap 242 can act as a foundation for disposing the fill 252 into the hole 250, where the fill 252 is disposed on the first surface 230 and accumulates through the hole 250 towards the second external surface 206.

The first end cap 242, the internal surface 210, and the fill 252 can form an electrically conductive via. The first end cap 242 and the fill 252 can be electrically conductive. The first end cap 242 and the fill 252 can establish an electrical pathway from the first external surface 204 to the second external surface 206. The electrically conductive via can be elongate about the central axis 208, such that the second external surface 206 is opposite the first external surface 204 along the central axis 208.

The electrical component can also include a second end cap 260. The end cap 260 can be formed of a third electrically conductive layer and a fourth electrically conductive layer. The third electrically conductive layer can extend along the second external surface 206 of the substrate 202. For example, the third electrically conductive layer can extend along a direction perpendicular to the central axis 208. The third electrically conductive layer can extend along the T direction of the substrate 202. The third electrically conductive layer can further define a first surface and a second surface. The first surface can face the second external surface 206 of the substrate 202. In some cases, the first surface can directly contact the second external surface 206. In some cases, the first surface can contact an adhesion layer disposed between the second external surface 206 and the first surface. The first surface can extend over the second external surface 206. The second surface can face opposite the first surface. The second surface can face the interior of the hole defined by the substrate 202. The second surface can extend over the second external surface 206.

Further, the third electrically conductive layer can define first and second terminal ends. The length of the third electrically conductive layer can terminate at the terminals ends. The first terminal end can be disposed more proximate to the internal surface 210 compared to the second terminal end. In some cases, the first terminal end can be coplanar with the second external surface 206, such that the first terminal end extends in the direction of the central axis 208 along the internal surface 210. In some cases the first terminal end can terminate along the second external surface 206, such that the terminal end fails to enter any gap defined by the internal surface 210. Likewise, the second terminal end can be coplanar with the second external surface 206, such that the second terminal end extends along the direction of the central axis 208 and along an external surface 226 of the substrate 202. In some cases the second terminal end can terminate along the second external surface 206, such that the second terminal end 224 fails to extend along the direction of the central axis 208.

The third electrically conductive layer can be disposed onto the first external surface 204, or alternatively onto an adhesion layer, through various manufacturing processes, such as electroplating, PVD, ALD, CVD, and the like. The third electrically conductive layer can be electrically conductive. For example, the third electrically conductive layer can be composed of any one of copper, silver, gold, platinum, aluminum, palladium. In some examples, the metal can be a pure metal, meaning that the metal is not alloyed with other metals. In other examples, the metal can be an alloy.

The electrical component can also have a fourth electrically conductive layer. The second electrically conductive layer can be bonded to the third electrically conductive layer. The fourth electrically conductive layer can be directly bonded to the third electrically conductive layer. Further, the fourth electrically conductive layer may span an opening defined by the internal surface 210 of the substrate 202. For example, the fourth electrically conductive layer can define a plane that is parallel to a plane defined by the length of the third electrically conductive layer. The fourth electrically conductive layer can define a first surface and a second surface. The first surface can extend perpendicular over the second external surface 206 and can span the opening defined by the internal surface 210 of the substrate 202. The first surface can bond or adhere to the second surface of the third electrically conductive layer. The first surface can bond or adhere to the first terminal end of the third electrically conductive layer. The second surface can face opposite the first surface. The fourth electrically conductive layer can be disposed atop the third electrically conductive layer. During manufacturing, the fourth electrically conductive layer can be liquified and disposed atop the third electrically conductive layer. Alternatively, the substrate 202 can be placed in a bath of the liquified metal for the fourth electrically conductive layer. The material of the fourth electrically conductive layer may fail to adhere or bond to the other surfaces of the substrate 202, such as the internal surface 210 and the external surface 206 (e.g., due to the composition of the substrate 202 or a wetting mitigation agent). The liquified metal can cool and solidify thereby forming the second end cap 260. The second end cap 260 can include the fourth electrically conductive layer, the third electrically conductive layer, or both.

The second surface can in some cases be flush with the second external surface 206, such that the second surface is coplanar with the second external surface 206. Alternatively, the second surface can extend away from the second external surface 206 along the direction of the central axis 208, such that the second surface sits proud of the second external surface 206. In some cases, the second surface can form a plane that is parallel to the plane of the second external surface 206, the first external surface 204, or both. Alternatively, the second surface can depress or sag towards the first external surface 204, which may be due in part to the lack of physical support in a central region of the via when the second end cap 260 is applied to the substrate 202. Likewise, the first surface of the fourth electrically conductive layer can in some cases form a plane that is parallel to the plane of the first external surface 204, the second external surface 206, or both. In some cases, the first surface can depress or sag towards the first external surface 204.

The fourth electrically conductive layer can be electrically conductive. The fourth electrically conductive layer can be composed of a metal. For example, the fourth electrically conductive layer can be composed of tin. However, the fourth electrically conductive layer can be composed of other metals, such as copper, gold, silver, platinum, titanium, aluminum, nickel, tungsten, molybdenum, zinc, barium, boron, and palladium. When solidified, the second end cap can be processed in some cases to adjust the height of the second end cap 260 (e.g., by CMP etching, lasing, etc.). In some cases, the second end cap 260 can hermetically seal an electrically conductive via formed along the substrate 202.

In some cases, the fourth electrically conductive layer can be composed of a metal alloy. For example, the fourth electrically conductive layer can be composed of gold tin, although other alloys of the metals described above can also be used. A first liquified metal can be placed along the second external surface 206 as discussed above. Then, a second liquified metal can be placed atop the first liquified metal. The two liquified metals may diffuse to form an alloy.

1. A method for manufacturing an electrical component comprising:
disposing a first electrically conductive layer along an internal surface of a substrate between a first external surface and a second external surface of the substrate, wherein the internal surface extends from the first external surface toward the second external surface;
applying a wetting mitigation agent along a least a portion of the first electrically conductive layer;
disposing a second electrically conductive material to the first electrically conductive material, wherein the second electrically conductive material bonds to another portion of the electrically conductive material that is free of the wetting mitigation agent, thereby forming an end cap.

2. The method of claim 1, wherein the electrically conductive endcap, the internal surface, and the electrically conductive layer define an electrically conductive via, and wherein the electrically conductive via is unfilled between 10-98% of a length of the electrically conductive via, wherein the length runs along a central axis of the electrically conductive via.

3. The method of claim 2, wherein the disposing the second electrically conductive material further comprises hermetically sealing the electrically conductive via.

4. The method of claim 1, wherein disposing the first electrically conductive layer further comprising bonding the first electrically conductive layer to the internal surface.

5. The method of claim 1, further comprising disposing an adhesion layer between the internal surface and the electrically conductive layer.

6. The method of claim 5, wherein disposing the adhesion layer further comprises bonding the adhesion layer to the internal surface.

7. The method of claim 5, wherein disposing the second electrically conductive layer further comprises bonding the adhesion layer to the second electrically conductive layer.

8. The method of claim 1, further comprising curing the wetting mitigation agent.

9. The method of claim 1, wherein applying the wetting mitigation agent comprises dipping the first electrically conductive layer into a wetting mitigation agent bath.

10. The method of claim 1, wherein disposing the second electrically conductive layer further comprises soldering the second electrically conductive layer.

11. The method of claim 1, wherein the internal surface extends from the first external surface to the second external surface.

12. The method of claim 1, further comprising etching a portion of wetting mitigation agent, thereby exposing a portion of the first electrically conductive layer.

13. The method of claim 1, wherein the wetting mitigation agent comprises a polymer, polysulfide, or both.

14. The method of claim 1, wherein the substrate, the first electrically conductive layer, and the electrically conductive end cap define an electrically conductive via that establishes an electrical path from the first external surface to the second external surface.

15. The method of claim 1, wherein the electrical component further defines a sidewall, wherein the sidewall extends along the internal surface and between the first external surface and the second external surface, and wherein a first surface of the sidewall faces the internal surface of the substrate, and a second surface of the sidewall faces a central axis of the electrical component.

16. The method of claim 15, wherein the sidewall comprises the first electrically conductive layer, the wetting mitigation agent, an adhesion layer, or a combination thereof.

17. The method of claim 1, wherein the wetting mitigation agent comprises a wetting mitigation coating.

18. The method of claim 1, further comprising providing the substrate.

19. The method of claim 18, wherein the substrate comprises one of glass, silica, quartz, ceramic, and sapphire.

20. The method of claim 1, wherein the first electrically conductive layer comprises at least one of copper, gold, silver, platinum, titanium, aluminum, nickel, tungsten, molybdenum, zinc, barium, boron, and palladium, and the second electrically conductive layer comprises at least one of copper, gold, silver, platinum, titanium, aluminum, nickel, tungsten, molybdenum, zinc, barium, boron, and palladium.
